(19) United States
(12) Patent Application Publication
(10) Pub. No.: US 2025/0386650 A1
(43) Pub. Date: Dec. 18, 2025

(54) LIGHT EMITTING DEVICE MODULE

(71) Applicant: WOOREE E&L CO., LTD., Gyeonggi-do (KR)

(72) Inventors: Yong Jin LEE, Gyeonggi-do (KR); Eui Chul JUNG, Gyeonggi-do (KR); Dong Jin SHIN, Gyeonggi-do (KR)

(21) Appl. No.: 19/022,281

(22) Filed: Jan. 15, 2025

(30) Foreign Application Priority Data
Jun. 17, 2024 (KR) 10-2024-0078543

(51) Int. Cl. H10H 29/856

(52) U.S. Cl. CPC H10H 29/856

(57) ABSTRACT

The present disclosure relates to a light emitting device module including a circuit board, a semiconductor light emitting device mounted on the circuit board, a reflective layer including an opening through which the semiconductor light emitting device is exposed, and covering the circuit board, and a molding layer covering the semiconductor light emitting device and the reflective layer. A light emitting surface of the semiconductor light emitting device is formed on an upper surface facing vertically upward.

### CROSS-REFERENCE TO RELATED APPLICATION

This application claims the benefit of and priority to Korean Patent Application No. 10-2024-0078543, filed on Jun. 17, 2024, the entire disclosure(s) of which is hereby incorporated herein by reference in its entirety.

### FIELD

The present disclosure relates to a light emitting device module applied to a display device, and more specifically, relates to a light emitting device module capable of improving uniformity of an entire light source by controlling image imbalance.

### BACKGROUND

A light emitting device is a semiconductor device that uses a light emitting diode, and is widely used in various fields such as display devices, vehicle lamps, and general lighting. The light emitting diode has an advantage in that a life span is long, power consumption is low, and a response speed is fast. Accordingly, existing light sources are rapidly replaced with the light emitting device.

Meanwhile, light emitting diodes in the related art have been mainly used as backlight sources in display devices. Recently, display devices that directly implement images by using the light emitting diodes have been developed. This display is referred to as a micro LED display.

In a case of the micro LED display, micro LEDs are arrayed on a two-dimensional plane to correspond to each sub-pixel, and accordingly, a large number of the micro LEDs need to be disposed on a single substrate. However, a size of the micro LEDs is very small, for example, smaller than 200 micros or even smaller than 100 micros. Due to this small size, various problems arise. It is difficult to control the light emitting diode having the small size. Consequently, it is not easy to directly mount the light emitting diode on a display panel.

In addition, there is a problem of an image imbalance phenomenon in which light is concentrated at a center of the light emitting diode.

Korean Patent No. 10-2023-0028222 published in Feb. 28, 2023 is an example of the related art.

### SUMMARY

One object of the present disclosure is to provide a light emitting device module capable of solving a process control efficiency problem of a micro LED and efficiently control an image imbalance problem.

According to an aspect of the present disclosure, there is provided a light emitting device module including a circuit board, a semiconductor light emitting device mounted on the circuit board, a reflective layer including an opening through which the semiconductor light emitting device is exposed, and covering the circuit board, and a molding layer covering the semiconductor light emitting device and the reflective layer. A light emitting surface of the semiconductor light emitting device is formed on an upper surface facing vertically upward.

The present disclosure can improve process efficiency of a micro LED by providing the light emitting device module provided with the semiconductor light emitting device.

According to the aspect of the present disclosure, efficiency of a manufacturing process can be improved, and a problem of image imbalance can be effectively controlled by applying the molding layer and the diffusion pattern layer.

### BRIEF DESCRIPTION OF THE DRAWINGS

FIGS. 1a and 1b are schematic exploded perspective views of a light emitting device module according to one embodiment of the present disclosure.

FIGS. 2a and 2b are schematic plan views of the light emitting device module according to one embodiment of the present disclosure.

FIGS. 3a, 3b, and 3c are schematic vertical cross-sectional views of the light emitting device module shown in FIG. 2.

FIGS. 4a and 4b are schematic plan views of a light emitting device module according to another embodiment of the present disclosure.

FIGS. 5a and 5b are schematic vertical cross-sectional views of the light emitting device module shown in FIG. 4.

### DETAILED DESCRIPTION

Hereinafter, various embodiments of the present disclosure will be described in detail with reference to the accompanying drawings. However, in describing the present disclosure, when it is determined that detailed description of a related notice function or configuration may unnecessarily obscure the concept of the present disclosure, the detailed description will be omitted.

In one specific example, the present disclosure provides a light emitting device module applied to a display device.

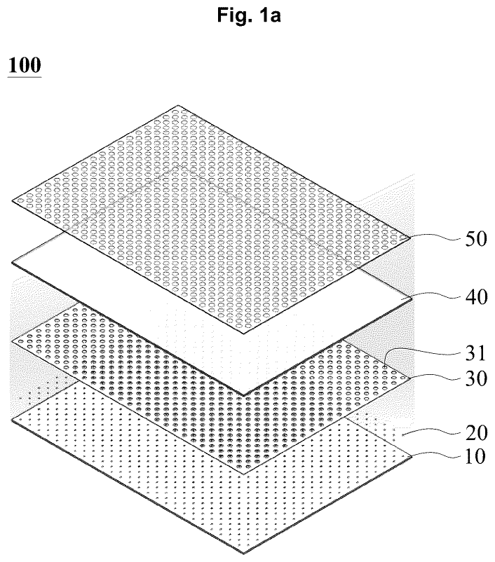

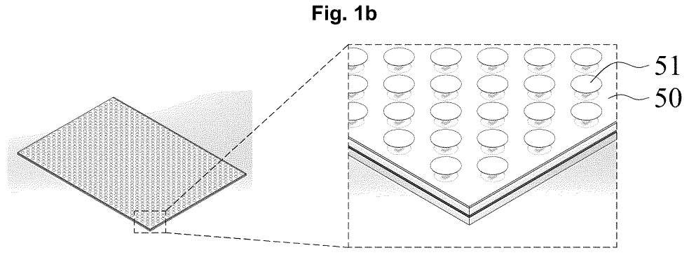

FIG. 1 is a schematic exploded perspective view of the light emitting device module according to one embodiment of the present disclosure. Specifically, FIG. 1a is an exploded perspective view of a light emitting device module 100, and FIG. 1b is a partially enlarged view of FIG. 1a.

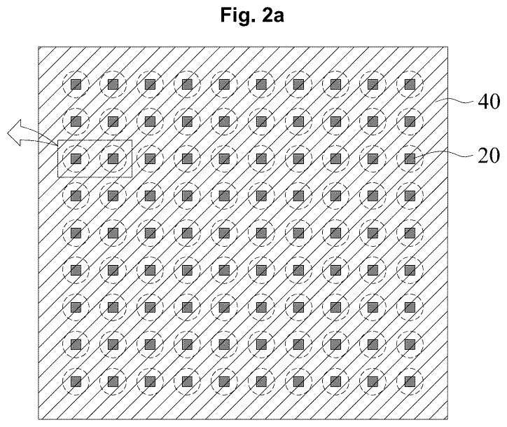

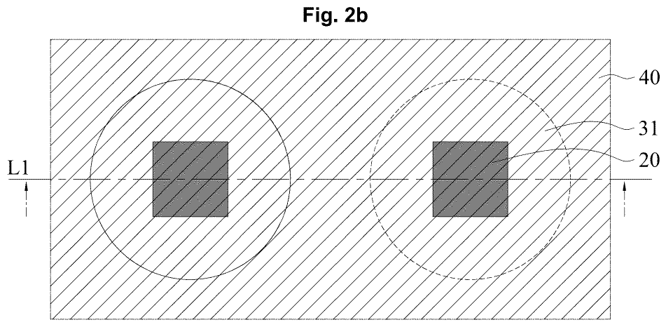

FIG. 2 is a schematic plan view of the light emitting device module according to one embodiment of the present disclosure. Specifically, FIG. 2a is a plan view of the light emitting device module 100, and FIG. 2b is a partially enlarged view of an area indicated by an arrow in FIG. 2a.

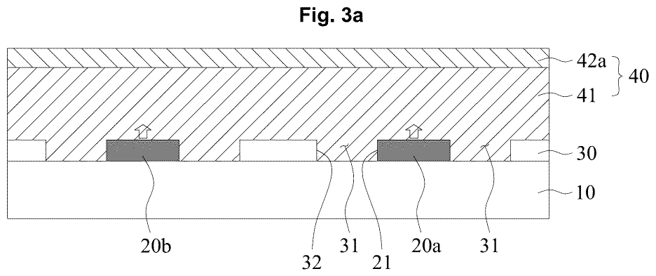

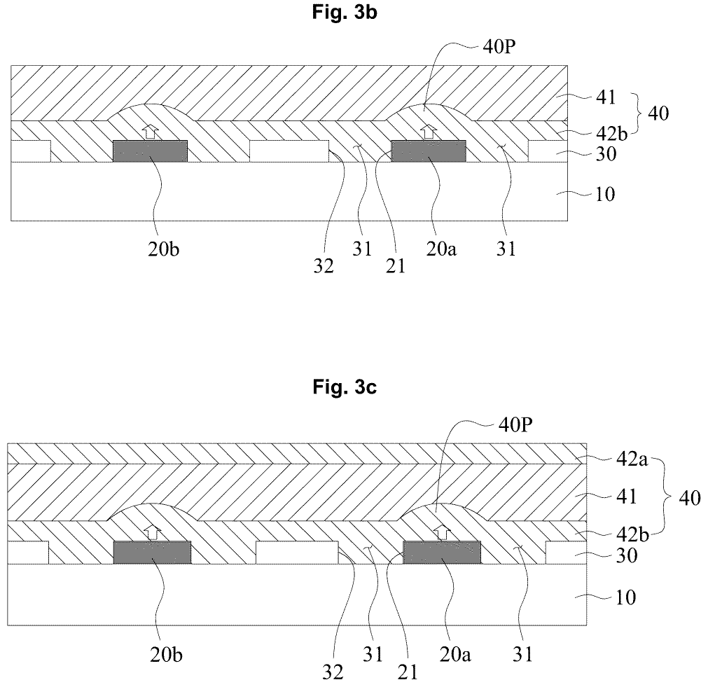

FIG. 3 is a schematic vertical cross-sectional view of the light emitting device module illustrated in FIG. 2. Specifically, FIG. 3 is a schematic vertical cross-sectional view taken along a cutting line L1 in FIG. 2b. Here, FIGS. 3a, 3b, and 3c are vertical cross-sectional views of the light emitting device module according to mutually different embodiments of the present disclosure.

Referring to FIGS. 1 to 3, the light emitting device module 100 of the present disclosure includes a circuit board 10, a semiconductor light emitting device 20, a reflective layer 30, and a molding layer 40.

The circuit board 10 refers to a board (PCB) on which a circuit pattern is formed, and may be formed as a flexible printed circuit board (FPCB) to ensure flexibility, for example.

The semiconductor light emitting device 20 is a part in which one or more light sources are arrayed on the circuit board 10 to emit light. Referring to FIG. 1 and FIG. 2, a plurality of the semiconductor light emitting devices 20 may be regularly aligned and disposed on the circuit board 10.

Referring to FIG. 3, the semiconductor light emitting device 20 in the present disclosure is a top view type light emitting diode in which a light emitting surface is formed on an upper surface facing vertically upward.

In a case of the top view type light emitting diode applied to the display device, there is a problem of image imbalance (for example, a hot spot) which occurs since light is concentrated in an area near the light emitting surface. According to the present disclosure, efficiency of a manufacturing process can be improved, and the problem of image imbalance can be effectively controlled by applying the molding layer 40.

The reflective layer 30 is formed on an upper surface of the circuit board 10, and is configured to cover the circuit board 10. The reflective layer 30 is formed of a material having high reflection efficiency. In this manner, since the light emitted from the semiconductor light emitting device 20 is reflected upward, the reflective layer 30 has a role to prevent a light loss.

The reflective layer 30 may be formed in a film form, and may be formed of a synthetic resin containing a white pigment to improve reflection and dispersion of the light. As the white pigment, for example, titanium oxide, aluminum oxide, zinc oxide, lead carbonate, barium sulfate, calcium carbonate, and the like may be used. Meanwhile, as the synthetic resin, for example, polyethylene terephthalate, polyethylene naphthalate, acrylic resin, polycarbonate, polystyrene, polyolefin, cellulose acetate, weather-resistant vinyl chloride, and the like may be used.

The reflective layer 30 includes an opening 31 through which the semiconductor light emitting device 20 is exposed. Accordingly, the reflective layer 30 provided with the opening 31 may be attached to the circuit board 10 on which the semiconductor light emitting device 20 is mounted. That is, description that the semiconductor light emitting device 20 is exposed by the opening 31 means that the reflective layer 30 does not cover the semiconductor light emitting device 20 in an area of the opening 31. Accordingly, even when any layer is formed on the upper surface of the semiconductor light emitting device 20, it should be interpreted that the semiconductor light emitting device 20 is exposed by the opening 31.

Meanwhile, a side surface 32 of the reflective layer 30 and a side surface 21 of the semiconductor light emitting device 20 may be in contact with or separated from each other. In terms of process efficiency, it is preferable that the side surface 32 of the reflective layer 30 and the side surface 21 of the semiconductor light emitting device 20 are disposed to be separate from each other.

The molding layer 40 is formed in an upper portion of the semiconductor light emitting device 20 and the reflective layer 30, and is configured to cover the semiconductor light emitting device 20 and the reflective layer 30. The molding layer 40 guides the light emitted from the semiconductor light emitting device 20 to be directed forward.

Meanwhile, the molding layer 40 may cover an upper portion of the circuit board 10. Here, the molding layer 40 may be configured to cover the upper portion of the circuit board 10 by coming into contact with or being separated from the upper surface of the circuit board 10.

A material of the molding layer 40 may be a light-transmitting thermoplastic resin, and for example, may be an epoxy resin or a silicone resin.

The molding layer 40 may be formed by using techniques such as lamination, spin coating, slit coating, and printing. For example, the molding layer 40 may be formed on the semiconductor light emitting device 20 by using a technique of vacuum lamination after bonding a heat-resistant layer 41 and a light diffusion layer 42 (to be described later). Specifically, in the present disclosure, a temperature of the vacuum lamination may be 90° C. to 130° C., and a pressurizing pressure may be 150 Kgf to 500 Kgf.

In one specific example, referring to FIG. 3, the molding layer 40 of the present disclosure includes the heat-resistant layer 41 and the light diffusion layer 42.

The heat-resistant layer 41 is formed of a high heat-resistant material, and has a role to protect the semiconductor light emitting device 20 from an external environment. For example, as described above, the high heat-resistant material may be an epoxy resin or a silicone resin.

The light diffusion layer 42 has a role to guide the light emitted from the semiconductor light emitting device 20 to be diffused forward.

In one specific example, the light diffusion layer 42 is provided on at least one of an upper surface and a lower surface of the heat-resistant layer 41. FIG. 3a shows an example in which the light diffusion layer 42a is provided on the upper surface of the heat-resistant layer 41, FIG. 3b shows an example in which the light diffusion layer 42b is provided on the lower surface of the heat-resistant layer 41, and FIG. 3c shows an example in which the light diffusion layers 42 and 42b are provided on the upper surface and the lower surface of the heat-resistant layer 41.

In one specific example, the light diffusion layer 42 includes a material which enables the light to be diffused into a transparent medium, for example, such as an epoxy resin. In the present disclosure, the light diffusion layer 42 may include a plurality of particles internally having hollow portions (or pores). The particles have a role to improve reflection and diffusion properties of the light.

In the present disclosure, the particles included in the light diffusion layer 42 may be formed of any one selected from silicon, silica, glass bubbles, polymethyl methacrylate (PMMA), urethane, Zn, Zr, Al2O3, and acrylic. Meanwhile, a particle diameter of the particles may be formed in a range of 1 μm to 20 μm, but the example is not limited thereto.

In one specific example, referring to FIG. 3a, when the light diffusion layer 42a is provided on the upper surface of the heat-resistant layer 41, the heat-resistant layer 41 fills at least a portion of the opening 31. Meanwhile, referring to FIGS. 3b and 3c, when the light diffusion layer 42b is provided on the lower surface of the heat-resistant layer 41, the light diffusion layer 42b fills at least a portion of the opening 31.

As described above, the reflective layer 30 includes the opening 31 through which the semiconductor light emitting device 20 is exposed. Accordingly, the side surface 32 of the reflective layer 30 and the side surface 21 of the semiconductor light emitting device 20 may be disposed to be separate from each other.

Here, for example, when the molding layer 40 is formed by using the technique of the vacuum lamination, the molding layer 40 may be formed such that the light diffusion layer 42b or the heat-resistant layer 41 fills at least a portion of the opening 31. In particular, by filling the opening 31 with the light diffusion layer 42b, the light emitted from the side surface of the semiconductor light emitting device 20 may be guided to be effectively diffused forward (that is, vertically upward in FIG. 3).

In one specific example, referring to FIGS. 3b and 3c, when the light diffusion layer 42b is provided on the lower surface of the heat-resistant layer 41, the light diffusion layer 42b includes a step region 40P covering each of the plurality of the semiconductor light emitting devices 20a and 20b. Here, the step region 40P is configured to protrude upward. That is, the step region 40P may be configured to protrude upward from a horizontal plane of the light diffusion layer 42b. Since the light diffusion layer 42b includes the step region 40P covering each of the plurality of the semiconductor light emitting devices 20a and 20b, a directional angle of the light emitted from the semiconductor light emitting devices 20a and 20b may be increased to control the problem of image imbalance.

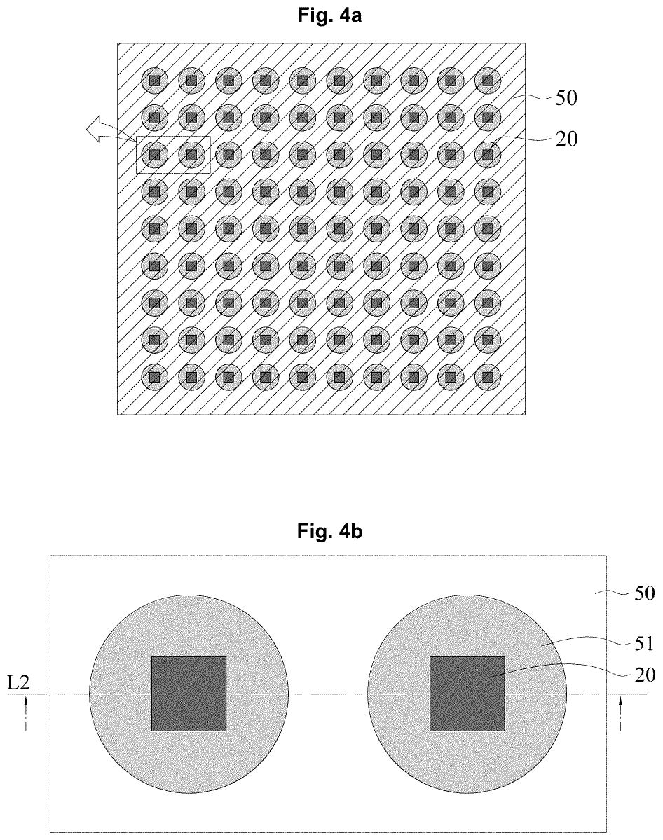

FIG. 4 is a schematic plan view of a light emitting device module according to another embodiment of the present disclosure. Specifically, FIG. 4a is a plan view of the light emitting device module, and FIG. 4b is a partially enlarged view of an area indicated by an arrow in FIG. 4a.

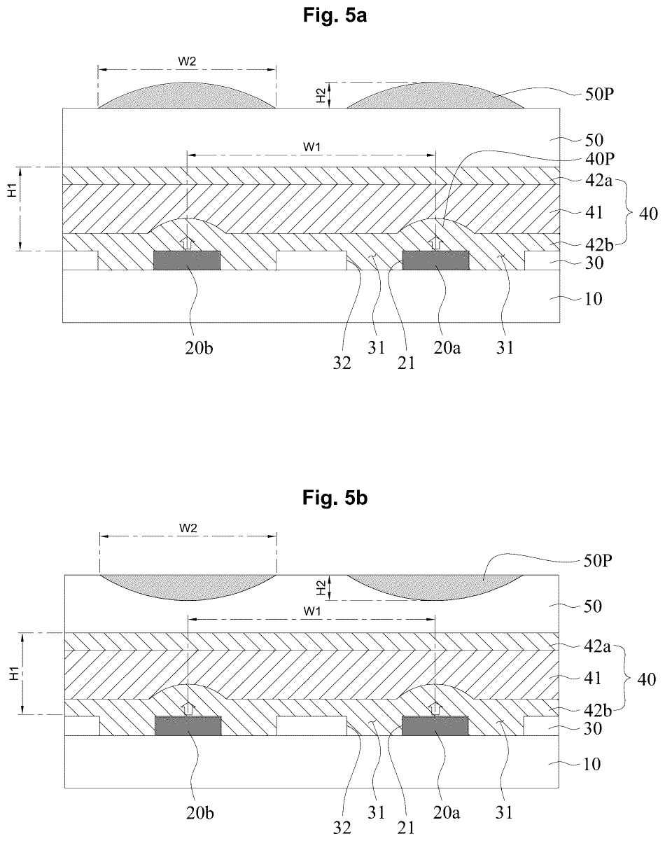

FIG. 5 is a schematic vertical cross-sectional view of the light emitting device module illustrated in FIG. 4. Specifically, FIG. 5 is a schematic vertical cross-sectional view taken along a cutting line L2 in FIG. 4b. Here, FIGS. 5a and 5b are vertical cross-sectional views of the light emitting device module according to mutually different embodiments of the present disclosure.

In one specific example, referring to FIGS. 4 and 5, the light emitting device module of the present disclosure further includes a diffusion pattern layer 50 covering the molding layer 40. Specifically, the diffusion pattern layer 50 is formed in an upper portion of the molding layer 40, and is configured to cover the molding layer 40.

The diffusion pattern layer 50 may be formed of a synthetic resin, for example, such as polyethylene terephthalate, polyethylene naphthalate, acrylic resin, polycarbonate, polystyrene, polyolefin, cellulose acetate, and weather-resistant polyvinyl chloride.

In one specific example, the diffusion pattern layer 50 includes a pattern area 50P covering the semiconductor light emitting device 20, and the pattern area 50P includes a light diffusing material or a light absorbing material.

The pattern area 50P may control the problem of image imbalance in such a manner that a light diffusing material is used to increase the directional angle by diffusing the light emitted from the semiconductor light emitting device 20, or may control the problem of image imbalance in such a manner that a light absorbing material is used to absorb the light.

In the present disclosure, for example, the light diffusing material included in the pattern area 50P may be one or more materials selected from TiO₂, CaCO₃, BaSO₄, Al₂O₃, and silicon.

The light absorbing material included in the pattern area 50P in the present disclosure may include a light absorbing dye, for example, such as carbon black. The light absorbing dye may be directly dispersed into a medium, or may be coated on a surface of organic or inorganic particles to be dispersed into the medium. Various types of organic or inorganic particles may be used to coat the light absorbing material. For example, particles obtained by coating TiO₂ or silica particles with the carbon black may be used.

The pattern area 50P may be formed by applying ink containing the light diffusing material or the light absorbing material to an upper surface of a polymer film in an emitting direction of the light, for example, by using a screen printer method.

In one specific example, the pattern area 50P may be configured such that a concentration of the light diffusing material or the light absorbing material decreases as the pattern area 50P is directed away from the center. The pattern area 50P is configured such that the concentration of the light diffusing material or the light absorbing material becomes higher at the center of the pattern area 50P, and light transmittance is reduced at the center of the pattern area 50P. In this manner, the problem of image imbalance caused by light concentration in a center region of the light emitting surface of the semiconductor light emitting device 20 may be effectively controlled.

In one specific example, the pattern area 50P is formed in a circular shape around the semiconductor light emitting device 20 covered by the pattern area 50P, and the pattern area 50P is configured such that a thickness decreases as the pattern area 50P is directed away from the center of the circular shape.

Since the pattern area 50P is formed in the circular shape around the semiconductor light emitting device 20, the light emitted from the semiconductor light emitting device 20 may be effectively covered and controlled.

In addition, since the thickness at the center of the pattern area 50P is formed to be largest, the problem of image imbalance may be effectively controlled by reducing the light transmittance at the center of the pattern area 50P.

In one specific example, the pattern area 50P has an upper surface having a convex curved shape, and is configured to protrude upward from a horizontal plane of the diffusion pattern layer 50 adjacent to the pattern area 50P.

In one specific example, the pattern area 50P has a lower surface having a concave curved shape, and is configured to be recessed downward from the horizontal plane of the diffusion pattern layer 50.

The pattern area 50P may form patterns of various shapes, such as squares and polygons as well as the above-described circular shape. In this case, the pattern area 50P is configured to protrude upward while the upper surface has the convex curved shape, or to be recessed downward while the lower surface has the concave curved shape. In this manner, the problem of image imbalance may be effectively controlled by reducing the light transmittance at the center of the pattern area 50P.

In one specific example, the light emitting device module 100 of the present disclosure is configured such that a width W2 of the pattern area 50P is smaller than a distance W1 between the centers of two adjacent semiconductor light emitting devices 20a and 20b.

Referring to FIG. 3, since the width W2 of the pattern area 50P is configured to be smaller than the distance W1 between the centers of the two adjacent semiconductor light emitting devices 20a and 20b, a plurality of the pattern areas 50P may be disposed to be separate from each other without overlapping each other. Accordingly, whereas the pattern area 50P is disposed to cover each of the semiconductor light emitting devices 20a and 20b, the pattern area 50P does not exist in a space between the semiconductor light emitting devices 20a and 20b. Therefore, the problem of image imbalance may be controlled by adjusting the light transmittance of the light emitting device module 100 as a whole.

In one specific example, the light emitting device module 100 of the present disclosure is configured such that a height H2 of the pattern area 50P is lower than a height H1 of the molding layer 40. When the height H2 of the pattern area 50P is too high, the light emitted from each of the semiconductor light emitting devices 20a and 20b may be blocked too much. Consequently, a problem may arise in that a light output at the center of each of the semiconductor light emitting devices 20a and 20b may be reduced compared to a periphery thereof.

Hereinafter, various embodiments of the present disclosure are described.

### EMBODIMENTS

Embodiment 1. A light emitting device module 100 comprising: a circuit board 10; a semiconductor light emitting device 20 mounted on the circuit board 10; a reflective layer 30 including an opening 31 through which the semiconductor light emitting device 20 is exposed, and covering the circuit board 10; and a molding layer 40 covering the semiconductor light emitting device 20 and the reflective layer 30, wherein a light emitting surface of the semiconductor light emitting device 20 is formed on an upper surface facing vertically upward.

Embodiment 2. The light emitting device module 100 of embodiment 1, wherein the molding layer 40 includes a heat-resistant layer 41 and a light diffusion layer 42.

Embodiment 3. The light emitting device module 100 of embodiment 2, wherein the light diffusion layer 42 is provided on at least one of an upper surface and a lower surface of the heat-resistant layer 41.

Embodiment 4. The light emitting device module 100 of embodiment 2, wherein the light diffusion layer 42 includes particles made of one selected from silicon, silica, glass bubbles, polymethyl methacrylate (PMMA), urethane, Zn, Zr, Al₂O₃, and acrylic.

Embodiment 5. The light emitting device module 100 of embodiment 3, wherein when the light diffusion layer 42 is provided on the upper surface of the heat-resistant layer 41, the heat-resistant layer 41 fills at least a portion of the opening 31, and when the light diffusion layer 42 is provided on the lower surface of the heat-resistant layer 41, the light diffusion layer 42b fills at least a portion of the opening 31.

Embodiment 6. The light emitting device module 100 of embodiment 3, wherein when the light diffusion layer 42 is provided on the lower surface of the heat-resistant layer 41, the light diffusion layer 42 includes a step region 40P covering the semiconductor light emitting device 20, and the step region 40P is configured to protrude upward.

Embodiment 7. The light emitting device module 100 of embodiment 1, further comprising: a diffusion pattern layer 50 covering the molding layer 40.

Embodiment 8. The light emitting device module 100 of embodiment 7, wherein the diffusion pattern layer 50 includes a pattern area 50P covering the semiconductor light emitting device 20, and the pattern area 50P includes a light diffusing material or a light absorbing material.

Embodiment 9. The light emitting device module 100 of embodiment 8, wherein in the pattern area 50P, a concentration of the light diffusing material or the light absorbing material decreases as the pattern area 50P is directed away from a center of the pattern area 50P.

Embodiment 10. The light emitting device module 100 of embodiment 8, wherein the pattern area 50P is formed in a circular shape around the semiconductor light emitting device 20 covered by the pattern area 50P, and a thickness of the pattern area 50P decreases as the pattern area 50P is directed away from a center of the circular shape.

Embodiment 11. The light emitting device module 100 of embodiment 8, wherein the pattern area 50P has an upper surface having a convex curved shape, and is configured to protrude upward from a horizontal plane of the diffusion pattern layer 50 adjacent to the pattern area 50P.

Embodiment 12. The light emitting device module 100 of embodiment 8, wherein the pattern area 50P has a lower surface of a concave curved shape, and is configured to be recessed downward from a horizontal plane of the diffusion pattern layer 50.

Embodiment 13. The light emitting device module 100 of embodiment 8, wherein a width W2 of the pattern area 50P is smaller than a distance W1 between centers of two adjacent semiconductor light emitting devices 20a and 20b.

Embodiment 14. The light emitting device module 100 of embodiment 8, wherein a height H2 of the pattern area 50P is lower than a height H1 of the molding layer 40.

### DETAILED DESCRIPTION OF MAIN ELEMENTS

10: circuit board
20: semiconductor light emitting device
30: reflective layer
40: molding layer
50: diffusion pattern layer

What is claimed is:

1. A light emitting device module comprising:
a circuit board;
a semiconductor light emitting device mounted on the circuit board;
a reflective layer including an opening through which the semiconductor light emitting device is exposed, and covering the circuit board; and
a molding layer covering the semiconductor light emitting device and the reflective layer,
wherein a light emitting surface of the semiconductor light emitting device is formed on an upper surface facing vertically upward.

2. The light emitting device module of claim 1, wherein the molding layer includes a heat-resistant layer and a light diffusion layer.

3. The light emitting device module of claim 2, wherein the light diffusion layer is provided on at least one of an upper surface and a lower surface of the heat-resistant layer.

4. The light emitting device module of claim 2, wherein the light diffusion layer includes particles made of one selected from silicon, silica, glass bubbles, polymethyl methacrylate (PMMA), urethane, Zn, Zr, Al₂O₃, and acrylic.

5. The light emitting device module of claim 3, wherein when the light diffusion layer is provided on the upper surface of the heat-resistant layer, the heat-resistant layer fills at least a portion of the opening, and when the light diffusion layer is provided on the lower surface of the heat-resistant layer, the light diffusion layer fills at least a portion of the opening.

6. The light emitting device module of claim 3, wherein when the light diffusion layer is provided on the lower surface of the heat-resistant layer, the light diffusion layer includes a step region covering the semiconductor light emitting device, and the step region is configured to protrude upward.

7. The light emitting device module of claim 1, further comprising:
a diffusion pattern layer covering the molding layer.

8. The light emitting device module of claim 7, wherein the diffusion pattern layer includes a pattern area covering the semiconductor light emitting device, and the pattern area includes a light diffusing material or a light absorbing material.

9. The light emitting device module of claim 8, wherein in the pattern area, a concentration of the light diffusing material or the light absorbing material decreases as the pattern area is directed away from a center of the pattern area.

10. The light emitting device module of claim 8, wherein the pattern area is formed in a circular shape around the semiconductor light emitting device covered by the pattern area, and a thickness of the pattern area decreases as the pattern area is directed away from a center of the circular shape.

11. The light emitting device module of claim 8, wherein the pattern area has an upper surface having a convex curved shape, and is configured to protrude upward from a horizontal plane of the diffusion pattern layer adjacent to the pattern area.

12. The light emitting device module of claim 8, wherein the pattern area has a lower surface of a concave curved shape, and is configured to be recessed downward from a horizontal plane of the diffusion pattern layer.

13. The light emitting device module of claim 8, wherein a width of the pattern area 50P is smaller than a distance between centers of two adjacent semiconductor light emitting devices.

14. The light emitting device module of claim 8, wherein a height of the pattern area is lower than a height of the molding layer.
